(19) United States
(12) Patent Application Publication
(10) Pub. No.: US 2011/0079840 A1
(43) Pub. Date: Apr. 7, 2011

(54) MEMORY CELL AND MANUFACTURING METHOD THEREOF AND MEMORY STRUCTURE

(75) Inventors: Jyun-Siang Huang, Hsinchu (TW); Wen-Jer Tsai, Hsinchu (TW); Tien-Fan Ou, Hsinchu (TW); Cheng-Hsien Cheng, Hsinchu (TW)

(73) Assignee: MACRONIX INTERNATIONAL CO., LTD., Hsinchu (TW)

(21) Appl. No.: 12/571,692

(22) Filed: Oct. 1, 2009

(51) Int. Cl. H01L 29/792; H01L 21/336

(52) U.S. Cl. 257/325; 438/287; 257/324; 977/773; 257/E29.309; 257/E21.423

(57) ABSTRACT

A memory cell is provided. The memory cell includes a substrate, an isolation layer, a gate, a charge storage structure, a first source/drain region, a second source/drain region and a channel layer. The isolation layer is disposed over the substrate. The gate is disposed over the isolation layer. The charge storage structure is disposed over the isolation layer and the gate. The first source/drain region is disposed over the charge storage structure at two sides of the gate. The second source/drain region is disposed over the charge storage structure at top of the gate. The channel layer is disposed over the charge storage structure at sidewall of the gate and is electrically connected with the first source/drain region and the second source/drain region.

### BACKGROUND OF THE INVENTION

1. Field of the Invention

The invention relates to a memory cell, a manufacturing method thereof and a memory structure, and more particularly to a memory cell, a manufacturing method thereof and a memory structure capable of reducing an occurrence of punch-through phenomenon and having superior channel boosting capability.

2. Description of Related Art

A memory is a semiconductor device designed for storing information or data. As the functions of computer microprocessors become more and more powerful, programs and operations executed by software are increased correspondingly. As a consequence, the demand for high storage capacity memories is getting higher. The challenge of fabricating memories with large storage capacity and low manufacturing cost to satisfy such a demand is now a driving force for developing the techniques and processes of manufacturing highly integrated semiconductor devices.

Among various types of memory products, a non-volatile memory allows multiple-time data writing, reading and erasing operations, and the data stored therein can be retained even after the power to the memory is disconnected. With these advantages, the non-volatile memory has become one of the most widely adopted memories for personal computers and electronic equipments. In addition, a flash memory is a widely used non-volatile memory.

However, as the devices continue to miniaturize, the bit line punch-through phenomenon in the flash memory becomes more severe. Moreover, in an operation of the flash memory, the self-boosting of the program inhibit also faces the problem of leakage current, for example, a junction leakage or a gate induced drain leakage (GIDL), thereby causing boosting failure.

Hence, how to reduce an occurrence of the bit line punch-through phenomenon and obtain superior boosting capability has become an important task in the current development of the flash memory.

### SUMMARY OF THE INVENTION

One aspect of the invention is directed to a memory cell including a substrate, an isolation layer, a gate, a charge storage structure, first source/drain regions, a second source/drain region, and channel layers. The isolation layer is disposed over the substrate. The gate is disposed over the isolation layer. The charge storage structure is disposed over the isolation layer and the gate. The first source/drain regions are disposed over the charge storage structure at the two sides of the gate. The second source/drain region is disposed over the charge storage structure at top of the gate. The channel layers are disposed over the charge storage structure at sidewalls of the gate and electrically connected with the first source/drain region and the second source/drain region.

According to the memory cell illustrated in an embodiment of the invention, a material of the isolation layer is oxide or nitride, for example.

According to the memory cell illustrated in an embodiment of the invention, the charge storage structure includes a first dielectric layer, a charge trapping layer, and a second dielectric layer. The first dielectric layer is disposed over the isolation layer and the gate. The charge trapping layer is disposed over the first dielectric layer. The second dielectric layer is disposed over the charge trapping layer.

According to the memory cell illustrated in an embodiment of the invention, a material of the charge trapping layer is, for example, nitride or high dielectric constant materials.

According to the memory cell illustrated in an embodiment of the invention, the charge storage structure includes a first dielectric layer, a nano-crystal layer, and a second dielectric layer. The first dielectric layer is disposed over the isolation layer and the gate. The nano-crystal layer is disposed over the first dielectric layer. The second dielectric layer is disposed over the nano-crystal layer.

According to the memory cell illustrated in an embodiment of the invention, the charge storage structure includes an first dielectric layer, a polysilicon layer, and a second dielectric layer. The first dielectric layer is disposed over the isolation layer and the gate. The polysilicon layer is disposed over the first dielectric layer. The second dielectric layer is disposed over the polysilicon layer.

According to the memory cell illustrated in an embodiment of the invention, a material of the first source/drain regions and the second source/drain region is a first conductive type polysilicon or a first conductive type single crystal silicon, for instance.

According to the memory cell illustrated in an embodiment of the invention, a material of the channel layers is a second conductive type polysilicon, a second conductive type single crystal silicon, an undoped polysilicon, or an undoped single crystal silicon, for instance.

A memory cell according to an embodiment of the invention can reduce an occurrence of a punch-through phenomenon.

The invention is further directed to a manufacturing method of a memory cell. A substrate is provided. An isolation layer is formed over the substrate. A gate is formed over the isolation layer. A charge storage structure is formed over the surfaces of the gate and the isolation layer. A channel material layer is formed over the charge storage structure. First source/drain regions are formed in the channel material layer at the two sides of the gate and a second source/drain region is formed in the channel material layer at top of the gate.

According to the manufacturing method of the memory cell illustrated in an embodiment of the invention, a method of forming the channel material layer is to deposit an undoped polysilicon layer over the charge storage structure, for example.

According to an embodiment of the invention, a method of forming the channel material layer is to first form an amorphous silicon layer over the charge storage structure, for example. A metal induce lateral crystallization process is performed for transforming the amorphous silicon layer into a single crystal silicon layer.

According to the manufacturing method of the memory cell illustrated in an embodiment of the invention, after the channel material layer is formed and before the first source/drain regions and the second source/drain region are formed, an ion implantation process is further performed to the channel material layer.

According to the manufacturing method of the memory cell illustrated in an embodiment of the invention, a method of forming the first source/drain regions and the second source/drain region, for example, is to first form spacers over the channel material layer at the two sides of the gate. An ion implantation process is performed by using the spacers as a mask.

According to the manufacturing method of the memory cell illustrated in an embodiment of the invention, after the ion implantation process is performed, a thermal treatment is further carried out.

A manufacturing method of a memory cell according to an embodiment of the invention can increase an effective channel length of the memory cell.

The invention is further directed to a memory structure including a substrate and at least one memory array. The memory array is disposed over the substrate. The memory array includes an isolation layer, two select lines, a plurality of word lines, a charge storage structure, a plurality of first bit lines, a plurality of second bit lines and a plurality of channel layers. The isolation layer is disposed over the substrate. The select lines are disposed over the isolation layer. The word lines are disposed over the isolation layer and located between the select lines. The charge storage structure is disposed on isolation layer, the select lines, and the word lines. The first bit lines are disposed over the charge storage structure located at the two sides of the select lines and between the word lines, respectively. The second bit lines are disposed over the charge storage structure located at top of the select lines and the word lines, respectively. The channel layers are disposed over the charge storage structure located at sidewalls of the select lines and the word lines, respectively. Moreover, each of the channel layers is electrically connected with the corresponding first bit line and the corresponding second bit line.

According to the memory structure illustrated in an embodiment of the invention, the at least one memory array aforementioned includes a plurality of memory arrays, for example, and these memory arrays stack one another.

According to the memory structure illustrated in an embodiment of the invention, the memory structure further includes a plurality of dielectric layers, a first bit line contact, and a second bit line contact. The dielectric layers cover the memory arrays respectively and are configured to isolate the memory arrays. The first bit line contact is disposed in the dielectric layers and configured to electrically connect the rightmost first bit lines in the memory arrays. The second bit line contact is disposed in the dielectric layers and configured to electrically connect the leftmost first bit lines in the memory arrays.

According to the memory structure illustrated in an embodiment of the invention, a material of each of the dielectric layers is oxide or nitride, for instance.

According to the memory structure illustrated in an embodiment of the invention, each of the dielectric layers is a composite dielectric layer, for instance.

A memory structure according to an embodiment of the invention can have superior channel boosting capability.

In light of the foregoing, in the invention, since the channel layers are disposed over the isolation material and do not contact with the substrate, the channel layers can achieve fully-depletion and prevent leakage current in the operation process, thereby having superior channel boosting capability. In addition, in the invention, the length of the channel region can be controlled through adjusting the height of the gate. Hence, the effective channel length is increased without increasing the width of the gate so as to reduce the occurrence of the punch-through phenomenon.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1D are cross sectional views illustrating a flow diagram of manufacturing a memory cell according to an embodiment of the invention.

FIG. 2 is a schematic cross-sectional view illustrating a memory structure according to an embodiment of the invention.

FIG. 3 is a schematic cross-sectional view illustrating a memory structure according to another embodiment of the invention.

### DESCRIPTION OF EMBODIMENTS

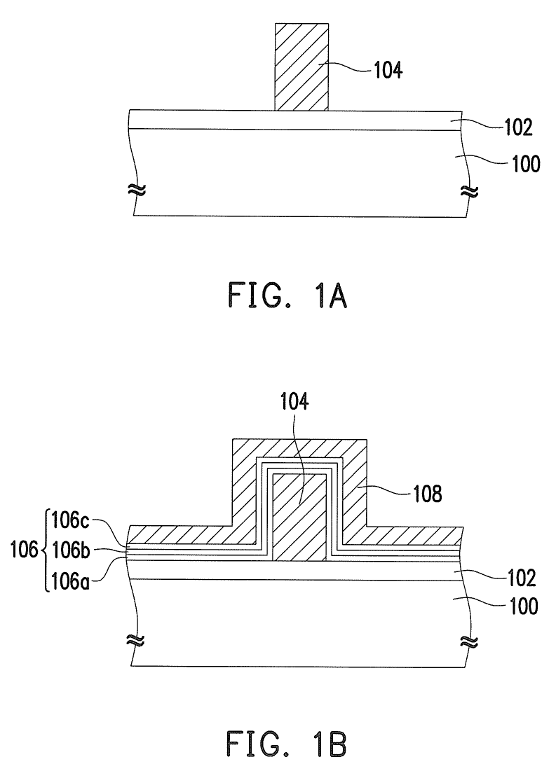

FIGS. 1A-1D are cross sectional views illustrating a flow diagram of manufacturing a memory cell according to an embodiment of the invention. Referring to FIG. 1A, a substrate 100 is provided. The substrate 100 is, for example, a silicon substrate. Then, an isolation layer 102 is formed over the substrate 100. A method of forming the isolation layer 102 is, for example, a chemical vapor deposition (CVD). A material of the isolation layer 102 is oxide or nitride, for instance. A gate 104 is formed over the isolation layer 102. In a method of forming the gate 104, an undoped polysilicon layer is deposited over the isolation layer 102, and a patterning process is performed, for instance. In addition, after the undoped polysilicon layer is deposited and before the patterning process is performed, an ion implantation process is further performed to implant a P-type dopant into the polysilicon layer.

Thereafter, referring to FIG. 1B, a charge storage structure 106 is formed over the isolation layer 102 and the gate 104. In the present embodiment, in a method of forming the charge storage structure 106, a dielectric layer 106a, a charge trapping layer 106b, and a dielectric layer 106c are sequentially formed over the isolation layer 102 and the gate 104. A material of the dielectric layer 106a is, for example, oxide. A material of the charge trapping layer 106b is nitride or high dielectric constant materials, for example. A material of the dielectric layer 106c is, for example, oxide. In another embodiment, in the method of forming the charge storage structure, a first dielectric layer, a nano-crystal layer, and a second dielectric layer are sequentially formed over the isolation layer 102 and the gate 104. A material of the nano-crystal layer is silicon, germanium, or metals, for example. In another embodiment, in the method of forming the charge storage structure, an first dielectric layer, a polysilicon layer, and a second dielectric layer are sequentially formed over n the isolation layer 102 and the gate 104. The polysilicon layer is used as a floating gate of the memory cell. Next, a channel material layer 108 is formed over the charge storage structure 106. A material of the channel material layer 108 is undoped polysilicon, for example, and a method of forming thereof is a CVD. Moreover, the material of the channel material layer 108 also can be undoped single crystal silicon. In a method of forming thereof, an amorphous silicon layer is formed over the charge storage structure 106. Then, a metal induce lateral crystallization process is performed to transform the amorphous silicon layer into a single crystal silicon layer. Additionally, in order to control a threshold voltage (Vt) of the memory cell, after the channel material layer 108 is formed, an ion implantation process is optionally performed to the channel material layer 108 so as to implant a dopant into the channel material layer 108. In the present embodiment, the P-type dopant is implanted into the channel material layer 108 in the ion implantation process, for instance.

Afterwards, referring to FIG. 1C, spacers 110 are formed over the channel material layer 108 at the two sides of the gate 104. A material of the spacers 110 includes oxide, for example. In a method of forming the spacers 110, a spacer material layer is conformally formed over the channel material layer 108, and an anisotropic etching process is then performed. Next, the spacers 110 are adopted as a mask in an ion implantation process 112 to implant the dopant into the channel material layer 108 for foaming doped regions 114. It should be noted that the dopant implanted in this step and the dopant implanted in the step illustrated in FIG. 1B have different conductive types. In other words, the dopant implanted in this step is the N-type dopant.

Thereafter, referring to FIG. 1D, a the mal treatment is performed so as to form source/drain regions 116 in the channel material layer 108 at the two sides of the gate 104 and a source/drain region 118 in the channel material layer 108 at top of the gate 104 for completing the manufacture of a memory cell 10. At this time, the remaining channel material layer 108 is used as channel layers 120 of the memory cell 10. The purpose of carrying out the thermal treatment is to further diffuse the dopant in the doped regions 114 at the two sides of the gate 104 to below the spacers 110. It should be noted that the thermal treatment can be a thermal treatment performed in the subsequent process or an additional thermal treatment performed independently.

FIG. 1D is used as an example in the following to illustrate the memory cell of the invention.

Referring to FIG. 1D, the memory cell 10 includes the substrate 100, the isolation layer 102, the gate 104, the charge storage structure 106, the source/drain regions 116, the source/drain region 118, and the channel layers 120. The isolation layer 102 is disposed over the substrate 100. The gate 104 is disposed over the isolation layer 102. The charge storage structure 106 is disposed over the isolation layer 102 and the gate 104. The source/drain regions 116 are disposed over the charge storage structure 106 at the two sides of the gate 104. The source/drain region 118 is disposed over the charge storage structure 106 at top of the gate 104. The channel layers 120 are disposed over the charge storage structure 106 at sidewalls of the gate 104 and electrically connected with the source/drain regions 116 and 118.

In the memory cell 10, since the channel layers 120 are disposed over the isolation material (the dielectric layer 106c of the charge storage structure 106) and not disposed in the substrate like the conventional flash memories, in the process of operating the memory cell 10, the leakage current can be prevented due to the channel layers 120 is not contacted with the substrate 100 so as to obtain superior channel boosting capability. Moreover, since the channel layers 120 do not contact with the substrate 100, leakage current can be prevented in the operation process. Furthermore, in the memory cell 10, the length of the channel region (that is, the height of the channel layers 120) can be controlled through adjusting the height of the gate 104. Hence, the effective channel length can be increased without increasing the width of the gate 104 so as to reduce the occurrence of the punch-through phenomenon.

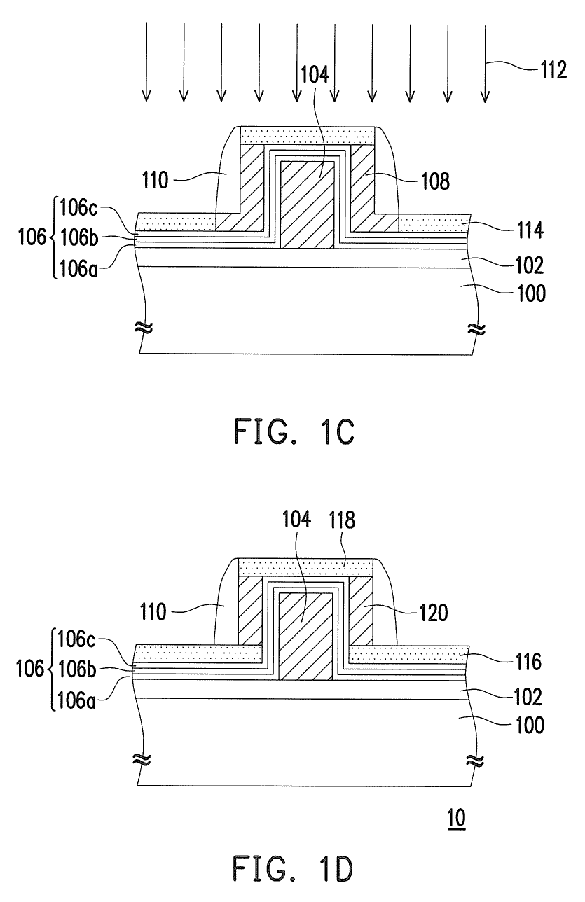

In the following, FIG. 2 is used to illustrate a memory structure formed by a plurality of memory cells 10.

FIG. 2 is a schematic cross-sectional view illustrating a memory structure according to an embodiment of the invention. Referring to FIG. 2, a memory structure 200 includes a substrate 202 and a memory array 204. The memory array 204 is disposed over the substrate 202. The memory array 204 includes an isolation layer 206, select lines 208-1 and 208-2, word lines 210-1˜210-n, a charge storage structure 212, bit lines 214, bit lines 216, spacers 217, and channel layers 218. The substrate 202, the isolation layer 206, the charge storage structure 212, the spacers 217, and the channel layers 218 are identical to the substrate 100, the isolation layer 102, the charge storage structure 106, the spacers 110, and the channel layers 120 in FIG. 1 D, and thus not repeated herein. The isolation layer 206 is disposed over the substrate 200. The select lines 208-1 and 208-2 are disposed over the isolation layer 206. The word lines 210-1˜210-n are disposed over the isolation layer 206 and located between the select lines 208-1 and 208-2. The charge storage structure 212 is disposed over the isolation layer 206, the select lines 208-1 and 208-2, and the word lines 210-1˜210-n. The bit lines 214 are disposed over the charge storage structure 212 at the two sides of the select lines 208-1 and 208-2 and between the word lines 210-1˜210-n. The bit lines 216 are disposed over the charge storage structure 212 at top of the select lines 208-1 and 208-2 and the word lines 210-1˜210-n. The channel layers 218 are disposed over the charge storage structure 212 at sidewalls of the select lines 208-1 and 208-2 and the word lines 210-1˜210-n. Additionally, each channel layer 218 is electrically connected to the corresponding bit line 214 and the corresponding bit line 216.

In the memory structure 200, since the channel layers 218 do not contact with the substrate 202, the channel layers 218 can achieve fully-depletion and prevent leakage current in the operation process, thereby having superior channel boosting capability. Furthermore, in the memory structure 200, a longer effective channel length is obtained, so that the occurrence of the punch-through phenomenon is reduced.

It should be noted that the memory structure of the invention not only can be a structure similar to the memory structure 200, but also can be a three-dimensional structure stacked by a plurality of the memory arrays.

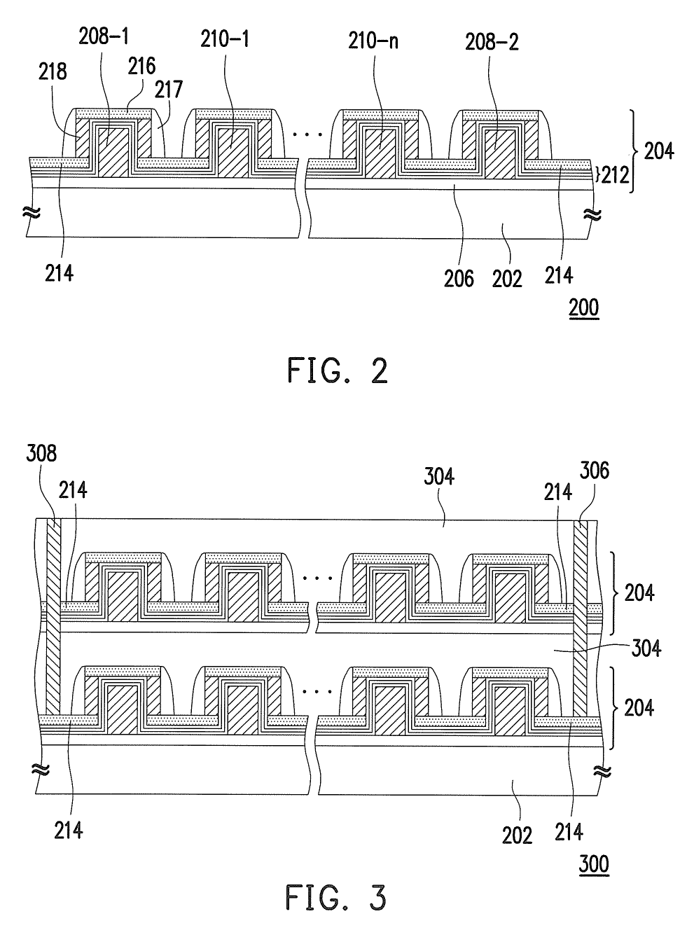

FIG. 3 is a schematic cross-sectional view illustrating a memory structure according to another embodiment of the invention. Referring to FIG. 3, a memory structure 300 is stacked by a plurality of memory arrays 204 over the substrate 202. The memory arrays 204 are illustrated in FIG. 2, and thus not illustrated herein. In the memory structure 300, dielectric layers 304 cover the memory arrays 204 and are configured to isolate the memory arrays 204. A material of each of the dielectric layers 304 is oxide or nitride, for example. In another embodiment of the invention, each of the dielectric layers 304 is a composite dielectric layer consisting of a plurality of the dielectric layers, for example. Besides, the bit line contact 306 is disposed in the dielectric layers 304 and configured to electrically connect the rightmost bit lines 214 in the memory arrays 204. The bit line contact 308 is disposed in the dielectric layers 304 and configured to electrically connect the leftmost bit lines 214 in the memory arrays 204. Hence, in the operation process, the memory arrays in every layer can be simultaneously operated by applying a voltage to the bit line contacts 306 and 308 respectively.

In the present embodiment, the memory structure 300 is stacked by two memory arrays 204. In other embodiments, the memory structure can also be stacked by more memory arrays 204 depending on actual demands.

Since the memory structure of the invention can be stacked by a plurality of memory arrays (i.e. memory arrays 204), the memory structure not only has superior channel boosting capability, prevents the leakage current, and reduce the occurrence of the punch-through phenomenon, but the memory array density over the unit area is also enhanced effectively.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A memory cell, comprising:
a substrate;
an isolation layer, disposed over the substrate;
a gate, disposed over the isolation layer;
a charge storage structure, disposed over the isolation layer and the gate;
first source/drain regions, disposed over the charge storage structure at two sides of the gate;
a second source/drain region, disposed over the charge storage structure at top of the gate; and
channel layers, disposed over the charge storage structure at sidewalls of the gate and electrically connected with the first source/drain region and the second source/drain region.

2. The memory cell as claimed in claim 1, wherein a material of the isolation layer comprises an oxide or a nitride.

3. The memory cell as claimed in claim 1, wherein the charge storage structure comprises:
a first dielectric layer, disposed over the isolation layer and the gate;
a charge trapping layer, disposed over the first dielectric layer; and
a second dielectric layer, disposed over the charge trapping layer.

4. The memory cell as claimed in claim 3, wherein a material of the charge trapping layer comprises a nitride or a high dielectric constant material.

5. The memory cell as claimed in claim 1, wherein the charge storage structure comprises:
a first dielectric layer, disposed over the isolation layer and the gate;
a nano-crystal layer, disposed over the first dielectric layer; and
a second dielectric layer, disposed over the nano-crystal layer.

6. The memory cell as claimed in claim 1, wherein the charge storage structure comprises:
a first dielectric layer, disposed over the isolation layer and the gate;
a polysilicon layer, disposed over the first dielectric layer; and
a second dielectric layer, disposed over the polysilicon layer.

7. The memory cell as claimed in claim 1, wherein a material of the first source/drain regions and the second source/drain region comprises a first conductive type polysilicon or a first conductive type single crystal silicon.

8. The memory cell as claimed in claim 7, wherein a material of the channel layers comprises a second conductive type polysilicon, a second conductive type single crystal silicon, an undoped polysilicon, or an undoped single crystal silicon.

9. A method of manufacturing a memory cell, comprising:
providing a substrate;
forming an isolation layer over the substrate;
forming a gate over the isolation layer;
forming a charge storage structure over the gate and the isolation layer;
forming a channel material layer over the charge storage structure; and
forming first source/drain regions in the channel material layer at two sides of the gate and forming a second source/drain region in the channel material layer at top of the gate.

10. The method of manufacturing the memory cell as claimed in claim 9, wherein a method of forming the channel material layer comprises depositing an undoped polysilicon layer over the charge storage structure.

11. The method of manufacturing the memory cell as claimed in claim 9, wherein the method of forming the channel material layer comprises:
forming an amorphous silicon layer over the charge storage structure; and
performing a metal induced lateral crystallization process for transforming the amorphous silicon layer into a single crystal silicon layer.

12. The method of manufacturing the memory cell as claimed in claim 9, wherein after forming the channel material layer and before forming the first source/drain regions and the second source/drain region, the method further comprises performing an ion implantation process to the channel material layer.

13. The method of manufacturing the memory cell as claimed in claim 9, wherein a method of forming the first source/drain regions and the second source/drain region comprises:
forming a spacer over the channel material layer at the two sides of the gate; and
performing an ion implantation process by using the spacer as a mask.

14. The method of manufacturing the memory cell as claimed in claim 13, wherein after performing the ion implantation process, the method further comprises performing a thermal treatment.

15. A memory structure, comprising:
a substrate; and
at least one memory array, disposed over the substrate, wherein the memory array comprises:
an isolation layer, disposed over the substrate;
two select lines, disposed over the isolation layer;
a plurality of word lines, disposed over the isolation layer and located between the plurality of select lines;
a charge storage structure, disposed over the isolation layer, the plurality of select lines, and the plurality of word lines;
a plurality of first bit lines, disposed over the charge storage structure located at two sides of the plurality of select lines and between the plurality of word lines, respectively;
a plurality of second bit lines, disposed over the charge storage structure located at top of the plurality of select lines and the plurality of word lines, respectively; and
a plurality of channel layers, disposed over the charge storage structure located at sidewalls of the plurality of select lines and the plurality of word lines, respectively, and each of the plurality of channel layers electrically connecting with the corresponding first bit line and the corresponding second bit line.

16. The memory structure as claimed in claim 15, wherein the at least one memory array comprises a plurality of the memory arrays, and the plurality of memory array stacks one another.

17. The memory structure as claimed in claim 16, further comprising:
a plurality of dielectric layers, covering the plurality of memory arrays respectively and configured to isolate the plurality of memory arrays;
a first bit line contact, disposed in the dielectric layers and configured to electrically connect the rightmost first bit lines in the plurality of memory arrays; and
a second bit line contact, disposed in the dielectric layers and configured to electrically connect the leftmost first bit lines in the plurality of memory arrays.

18. The memory structure as claimed in claim 17, wherein a material of each of the dielectric layers comprises oxide or nitride.

19. The memory structure as claimed in claim 17, wherein each of the dielectric layers comprises a composite dielectric layer.
